(19) United States
(12) Patent Application Publication
(10) Pub. No.: US 2015/0276858 A1
(43) Pub. Date: Oct. 1, 2015

(54) TEST APPARATUS AND CIRCUIT SUBSTRATE UNIT

(71) Applicant: ADVANTEST CORPORATION, Tokyo (JP)

(72) Inventors: Hidehiko YASUNO, Gunma (JP); Chizuru ARAI, Saitama (JP)

(73) Assignee: ADVANTEST CORPORATION, Tokyo (JP)

(21) Appl. No.: 14/226,777

(22) Filed: Mar. 26, 2014

(51) Int. Cl. G01R 31/28

(52) U.S. Cl. CPC G01R 31/2874

(57) ABSTRACT

A test apparatus that tests a device under test, comprising first and second test substrates facing each other; test circuits provided respectively on a first substrate surface of the first test substrate facing the second test substrate and a second substrate surface of the second test substrate facing the first test substrate; a first cooling section provided on the first substrate surface of the first test substrate to house the test circuit and to have a cooling medium introduced therein; and a second cooling section provided on the second substrate surface of the second test substrate to house the test circuit and to have a cooling medium introduced therein. The first and second cooling sections include respective contact portions in contact with each other, and each contact portion has a connection opening that connects inside of the first cooling section and inside of the second cooling section to each other.

### BACKGROUND

1. Technical Field

The present invention relates to a test apparatus and a circuit substrate unit.

2. Related Art

A configuration is known in which an electrical circuit is covered with a water jacket and a cooling medium is introduced into the water jacket in order to cool the electrical circuit, such as shown in Patent Documents 1 to 4, for example.

### Patent Document 1: Japanese Patent Application Publication No. 2006-196766

### Patent Document 2: Japanese Patent Application Publication No. 2006-292226

### Patent Document 3: Japanese Patent Application Publication No. 2007-258458

### Patent Document 4: Japanese Patent Application Publication No. 2011-210813

In a case where the cooling medium is introduced into two water jackets using a single system, the water jackets are connected to each other by a bypass such as a tube. However, when the water jackets are connected by the bypass such as a tube, pressure loss occurs. Therefore, the flow rate of the cooling medium is reduced.

### SUMMARY

Therefore, it is an object of an aspect of the innovations herein to provide a test apparatus and a circuit substrate unit, which are capable of overcoming the above drawbacks accompanying the related art. The above and other objects can be achieved by combinations described in the claims. According to a first aspect of the present invention, provided is a test apparatus that tests a device under test, comprising a first test substrate and a second test substrate arranged facing each other; test circuits provided respectively on a first substrate surface of the first test substrate that faces the second test substrate and on a second substrate surface of the second test substrate that faces the first test substrate; a first cooling section that is provided on the first substrate surface of the first test substrate in a manner to house the test circuit, and is to have a cooling medium introduced therein; and a second cooling section that is provided on the second substrate surface of the second test substrate in a manner to house the test circuit, and is to have a cooling medium introduced therein. The first cooling section and the second cooling section include respective contact portions that are in contact with each other, and each contact portion is provided with a connection opening that connects inside of the first cooling section and inside of the second cooling section to each other.

According to a second aspect of the present invention, provided is a circuit substrate unit comprising a first circuit substrate and a second circuit substrate arranged facing each other; electrical circuits provided respectively on a first substrate surface of the first circuit substrate that faces the second circuit substrate and on a second substrate surface of the second circuit substrate that faces the first circuit substrate; a first cooling section that is provided on the first substrate surface of the first circuit substrate in a manner to house the electrical circuit, and is to have a cooling medium introduced therein; and a second cooling section that is provided on the second substrate surface of the second circuit substrate in a manner to house the electrical circuit, and is to have a cooling medium introduced therein. The first cooling section and the second cooling section include respective contact portions that are in contact with each other, and each contact portion is provided with a connection opening that connects inside of the first cooling section and inside of the second cooling section to each other.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test apparatus 10.

FIG. 2A shows an exemplary configuration of a circuit substrate unit 20 according to a first embodiment of the present invention.

FIG. 2B shows another exemplary configuration of the circuit substrate unit 20.

FIG. 2C shows a circuit substrate unit 21 as a comparative example.

FIG. 3 shows an example of a test substrate 22 in the circuit substrate unit 20.

FIG. 4 shows an exemplary configuration of the first test substrate 22-1, the first cooling section 50-1, and the third cooling section 50-3.

FIG. 5 shows an exemplary configuration of the second test substrate 22-2, the second cooling section 50-2, and the fourth cooling section 50-4.

FIG. 6 shows an exemplary cross section of the first test substrate 22-1, the second test substrate 22-2, the first cooling section 50-1, and the second cooling section 50-2 at the position of the line A-A′ shown in FIG. 4.

FIG. 7 shows an exemplary contact portion 56 and flow path 64.

FIG. 8 shows an exemplary cross section of the first test substrate 22-1, the second test substrate 22-2, the first cooling section 50-1, the second cooling section 50-2, and the fourth cooling section 50-4, at the position of the line B-B′ in FIG. 7.

FIG. 9 shows another exemplary configuration of the circuit substrate unit 20 according to a second embodiment.

FIG. 10 shows another exemplary configuration of the circuit substrate unit 20.

FIG. 11 shows an exemplary configuration of the third test substrate 22-3, the fifth cooling section 50-5, and the sixth cooling section 50-6.

FIG. 12 shows an exemplary configuration of the first test substrate 22-1, the third cooling section 50-3, and the first cooling section 50-1.

FIG. 13 shows an exemplary configuration of the second test substrate 22-2, the second cooling section 50-2, and the fourth cooling section 50-4.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

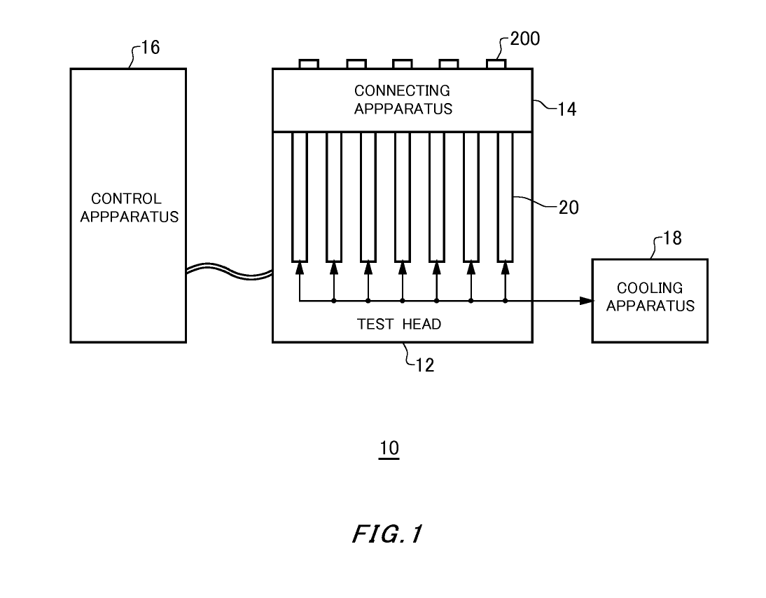

FIG. 1 shows an exemplary configuration of a test apparatus 10. The test apparatus 10 tests a device under test 200 such as a semiconductor circuit. The test apparatus 10 of this example includes a test head 12, a connecting apparatus 14, a control apparatus 16, a cooling apparatus 18, and a plurality of circuit substrate units 20.

The connecting apparatus 14 has a device under test 200 mounted thereon. The connecting apparatus 14 of the present embodiment has a plurality of devices under test 200 mounted thereon. The plurality of circuit substrate units 20 are electrically connected to the devices under test 200, via the connecting apparatus 14.

The circuit substrate units 20 function as test modules that tests the devices under test 200. The circuit substrate units 20 input test signals to the devices under test 200. The test signals have predetermined logic patterns, for example. The circuit substrate units 20 also receive response signals that are output by the devices under test 200 in response to the test signals. The circuit substrate units 20 determine pass/fail of the devices under test 200, based on the response signals. Each circuit substrate unit 20 is provided with a circuit substrate and an electrical circuit. Each circuit substrate unit 20 may include an electrical circuit that generates a test signal, and an electrical circuit that analyzes the response signal.

The test head 12 houses the plurality of circuit substrate units 20. The control apparatus 16 controls the circuit substrate units 20 within the test head 12. The cooling apparatus 18 cools the electrical circuits provided in each circuit substrate unit 20.

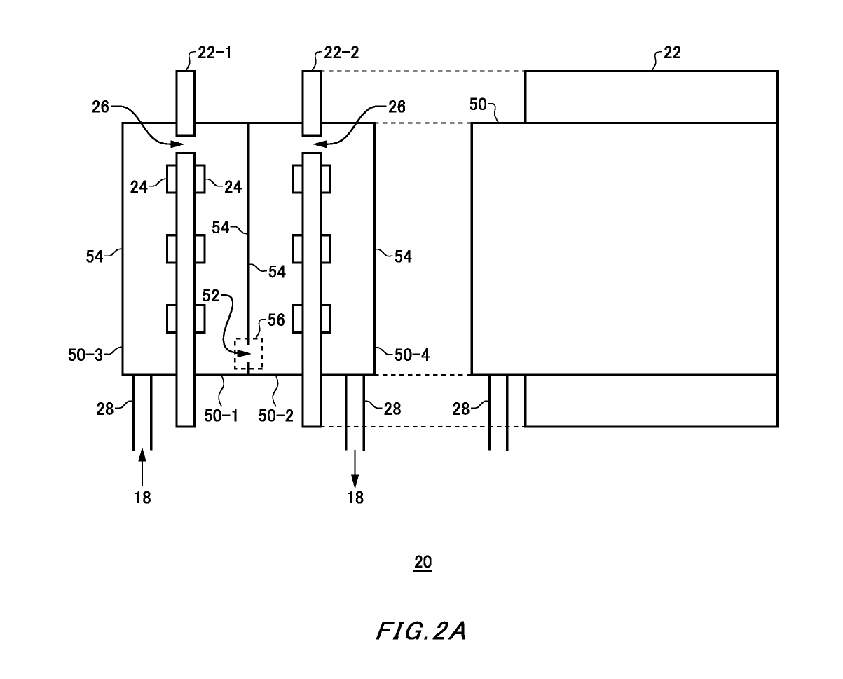

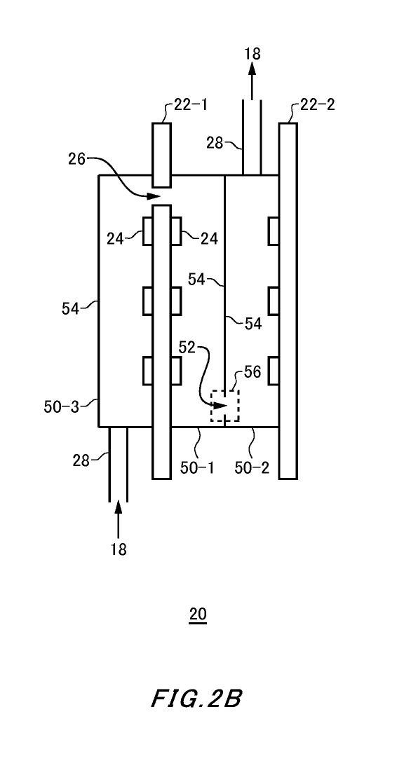

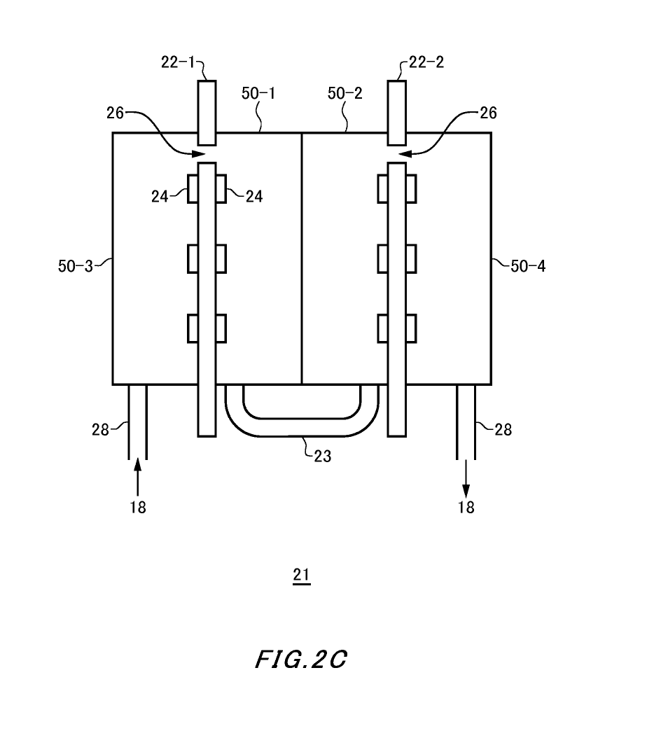

FIG. 2A shows an exemplary configuration of a circuit substrate unit 20 according to a first embodiment of the present invention. The left portion of FIG. 2A shows a cross section of the circuit substrate unit 20, and the right portion of FIG. 2A shows a side surface of the circuit substrate unit 20. The circuit substrate unit 20 in this example includes a first test substrate 22-1 and a second test substrate 22-2, which are examples of circuit substrates, a test circuit 24, which is an example of an electrical circuit, a first cooling section 50-1, a second cooling section 50-2, a third cooling section 50-3, a fourth cooling section 50-4, and a plurality of external connecting sections 28.

The first test substrate 22-1 and the second test substrate 22-2 are arranged opposite each other. The first test substrate 22-1 and the second test substrate 22-2 are print substrates, for example. A plurality of test circuits 24 are provided on each of a first substrate surface that is the surface of the first test substrate 22-1 facing the second test substrate 22-2, a third substrate surface that is a surface of the first test substrate 22-1 on the back of the first substrate surface, a second substrate surface that is a surface of the second test substrate 22-2 facing the first test substrate 22-1, and a fourth substrate surface that is a surface of the second test substrate 22-2 on the back of the second substrate surface.

The first cooling section 50-1 is provided on the first substrate surface of the first test substrate 22-1, in a manner to house the test circuits 24 provided on the first substrate surface of the first test substrate 22-1. The second cooling section 50-2 is provided on the second substrate surface of the second test substrate 22-2, in a manner to house the test circuits 24 provided on the second substrate surface of the second test substrate 22-2. The third cooling section 50-3 is provided on the third substrate surface of the first test substrate 22-1, in a manner to house the test circuits 24 provided on the third substrate surface of the first test substrate 22-1. The fourth cooling section 50-4 is provided on the fourth substrate surface of the second test substrate 22-2, in a manner to house the test circuits 24 provided on the fourth substrate surface of the second test substrate 22-2. A liquid cooling medium is introduced into each of the cooling sections 50.

The third cooling section 50-3 is connected to an external cooling apparatus 18, via an external connecting section 28. The cooling medium is introduced to the third cooling section 50-3 via the external connecting section 28. As a result, the test circuits 24 provided on the third substrate surface of the first test substrate 22-1 are cooled.

The first test substrate 22-1 has a through-hole 26 that connects the third substrate surface on which the third cooling section 50-3 is provided and the first substrate surface on which the first cooling section 50-1 is provided. The cooling medium is introduced into the first cooling section 50-1 through the through-hole 26. As a result, the test circuits 24 provided on the first substrate surface of the first test substrate 22-1 are cooled.

The first cooling section 50-1 and the second cooling section 50-2 each have a contact portion 56 connecting these cooling sections to each other. each contact portion 56 has a connection opening 52 that connects the inside of the first cooling section 50-1 to the inside of the second cooling section 50-2.

The first cooling section 50-1 and second cooling section 50-2 in this example each have a ceiling portion 54 provided facing a substrate surface of the corresponding test substrate 22. Each ceiling portion 54 may designate a region provided substantially parallel to the substrate surface of the test substrate 22. The contact portions 56 are provided in the ceiling portions 54. The connection opening 52 in this example is provided in a region sandwiched by the test substrates 22. The cooling medium is introduced into the second cooling section 50-2 through the connection opening 52. As a result, the test circuits 24 formed on the second substrate surface of the second test substrate 22-2 are cooled.

The second test substrate 22-2 has a through-hole 26 that connects the second substrate surface on which the second cooling section 50-2 is provided and the fourth substrate surface on which the fourth cooling section 50-4 is provided. The cooling medium is introduced into the fourth cooling section 50-4 through the through-hole 26. As a result, the test circuits 24 provided on the fourth substrate surface of the second test substrate 22-2 are cooled.

The fourth cooling section 50-4 is connected to the external cooling apparatus 18 via the external connecting section 28. In this example, the third cooling section 50-3 and the fourth cooling section 50-4 each have a region in which the respective test substrates 22 do not overlap, and the external connecting section 28 connects these regions to each other. The cooling medium is expelled from the fourth cooling section 50-4 through the external connecting section 28. As a result, the cooling medium circulates through the four cooling sections 50.

FIG. 2B shows another exemplary configuration of the circuit substrate unit 20. The circuit substrate unit 20 of this example does not include the fourth cooling section 50-4, the test circuits 24 on the fourth substrate surface of the second test substrate 22-2, and the through-hole 26 of the second test substrate 22-2, which were included in the circuit substrate unit 20 shown in FIG. 2A. Furthermore, the external connecting section 28 that was connected to the fourth cooling section 50-4 is now connected to the third cooling section 50-3. With this configuration, the cooling medium can circulate through the first cooling section 50-1, the second cooling section 50-2, and the third cooling section 50-3.

With the circuit substrate unit 20 of this example, when the cooling medium is supplied to a plurality of cooling sections 50 using a single system, the cooling sections 50 can be connected to each other without using the bypass. Therefore, the pressure loss in the bypass does not occur, and the cooling medium can flow efficiently. Furthermore, since the bypass is not used, the circuit substrate unit 20 can be made slimmer without requiring consideration of the limitation imposed by the bend radius of the bypass. Since there is no cost incurred by using a bypass component, the overall cost can be reduced.

FIG. 2C shows a circuit substrate unit 21 as a comparative example. The circuit substrate unit 21 includes a bypass section 23 for the circuit substrate unit 20, instead of the connection opening 52. The bypass section 23 connects the first cooling section 50-1 and the second cooling section 50-2.

As described above, when the bypass section 23 is used, pressure loss occurs in the bypass section 23. Furthermore, the slimming of the circuit substrate unit 21 cannot be realized since the limitation imposed by the bend radius of the bypass section 23 cannot be overcome. Yet further, providing the bypass section 23 increases the cost.

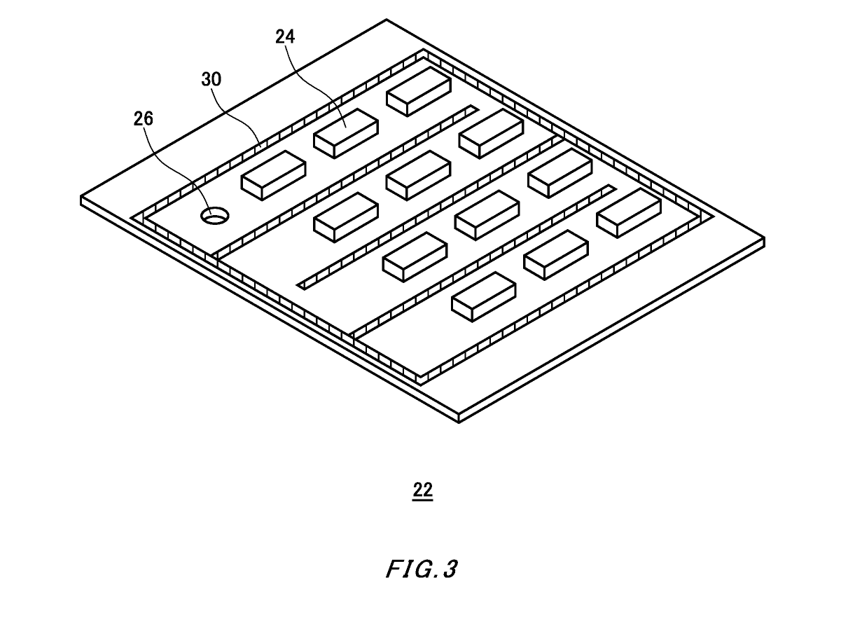

FIG. 3 shows an example of a test substrate 22 in the circuit substrate unit 20. Each test substrate 22 in the circuit substrate unit 20 may have the same configuration. The substrate surfaces on the front and back of the test substrate 22 may have the same configuration. FIG. 3 shows the first substrate surface of the first test substrate 22-1. The test substrate 22 includes a plurality of test circuits 24 on the front and back substrate surfaces. A through-hole 26 is formed that connects the front and back substrate surfaces are.

A sealing section 30 that surrounds the through-hole 26 and the plurality of test circuits 24 is formed on the front and back substrate surfaces of the test substrate 22. Furthermore, the sealing sections 30 are formed on the front and back substrate surfaces of the test substrate 22 with patterns corresponding to the flow paths of the cooling medium. The sealing section 30 in this example is provided to form a flow path that sequentially turns around in the progression direction of the cooling medium. Each cooling section 50 has wall portions that are in close contact with the sealing section 30, and the flow path of the cooling medium is formed by these wall portions. The through-hole 26 is formed at the end portion of the flow path.

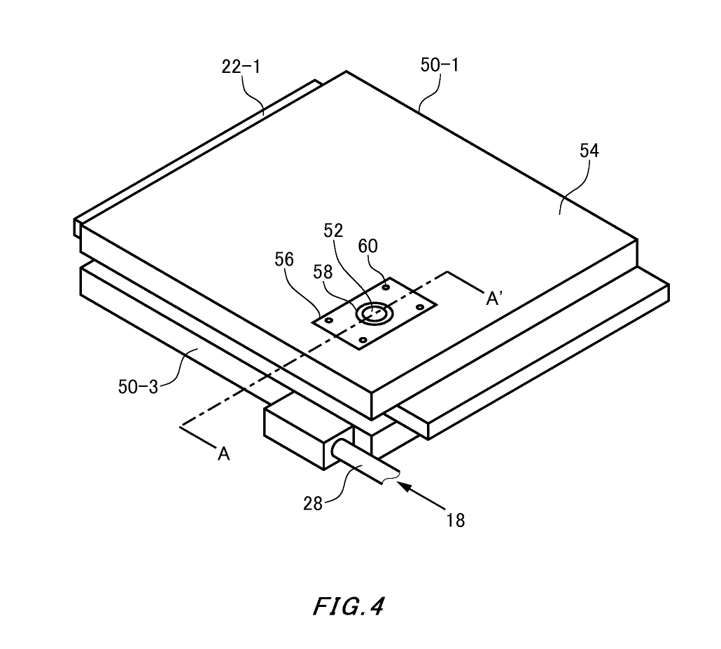

FIG. 4 shows an exemplary configuration of the first test substrate 22-1, the first cooling section 50-1, and the third cooling section 50-3. The first test substrate 22-1 of FIG. 4 may have the same configuration as the test substrate 22 shown in FIG. 3. The first cooling section 50-1 is provided on the first substrate surface of the first test substrate 22-1. The third cooling section 50-3 is provided on the third substrate surface of the first test substrate 22-1.

The external connecting section 28 is connected to the third cooling section 50-3. The external connecting section 28 introduces the cooling medium into the end portion of the flow path within the third cooling section 50-3 that is not provided with the through-hole 26. The introduced cooling medium moves through the flow path within the third cooling section 50-3, to be introduced into the first cooling section 50-1 from the through-hole 26.

The cooling medium introduced into the first cooling section 50-1 moves through the flow path in the first cooling section 50-1 and arrives at the end of the first cooling section 50-1 that is not provided with the through-hole 26. The ceiling portion 54 of the first cooling section 50-1 is provided with the contact portion 56 at a position opposite the end portion.

A connection opening 52 is formed within the contact portion 56. In this example, the connection opening 52 is provided at a position to not overlap with the through-hole 26. A groove 58 for mounting a seal ring is formed around the connection opening 52. A fastening section is formed in the contact portion 56. A plurality of screw holes 60 are one example of the fastening section. The fastening section is not limited to screws, and the contact portions 56 may be fastened to each other using a variety of means including rivets or fastener caulk. The connection opening 52 is formed in the region surrounded by the plurality of screw holes 60. The cooling medium is introduced from the first cooling section 50-1 into the second cooling section 50-2, via the connection opening 52.

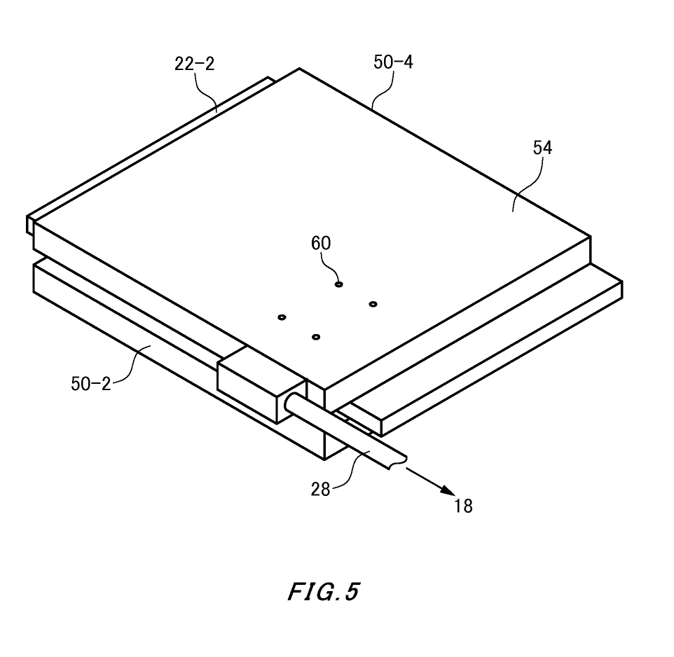

FIG. 5 shows an exemplary configuration of the second test substrate 22-2, the second cooling section 50-2, and the fourth cooling section 50-4. The second test substrate 22-2 and the like shown in FIG. 5 are stacked such that the respective screw holes 60 overlap at the same position. The second test substrate 22-2 of FIG. 5 may have the same configuration as the test substrate 22 shown in FIG. 3. The substrate surface shown in FIG. 3 corresponds to the fourth substrate surface of the second test substrate 22-2. The second cooling section 50-2 is provided on the second substrate surface of the second test substrate 22-2. The fourth cooling section 50-4 is provided on the fourth substrate surface of the second test substrate 22-2.

Although not shown in FIG. 5, the contact portion 56 and the connection opening 52 are provided on the second cooling section 50-2, at positions opposite the contact portion 56 and the connection opening 52 of the first cooling section 50-1. In the example of FIG. 5, the connection opening 52 of the first cooling section 50-1 is provided at a position overlapping the region surrounded by the screw holes 60 shown in FIG. 5. The contact portion 56 of the second cooling section 50-2 and the end portion of the flow path within the second cooling section 50-2 are provided opposite each other.

The cooling medium introduced into the second cooling section 50-2 propagates through the internal flow path, to be introduced into the fourth cooling section 50-4 from the through-hole 26 of the second test substrate 22-2. The through-hole 26 of the second test substrate 22-2 is provided at a position that does not overlap with the connection opening 52 of the second cooling section 50-2.

The cooling medium introduced into the fourth cooling section 50-4 propagates through the internal flow path, to arrive at the end portion of the flow path where the external connecting section 28 is provided. The external connecting section 28 transfers the cooling medium expelled from the fourth cooling section 50-4 to the cooling apparatus 18.

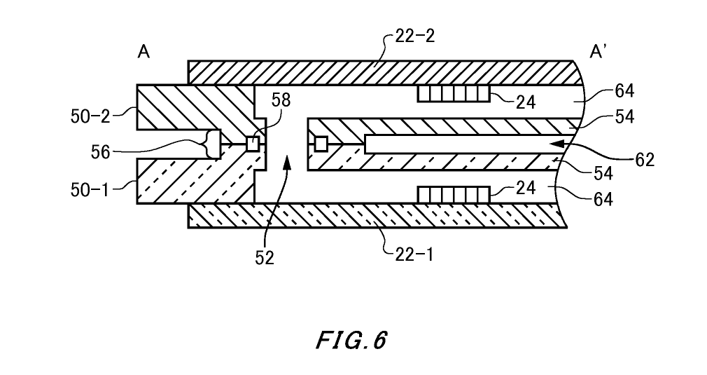

FIG. 6 shows an exemplary cross section of the first test substrate 22-1, the second test substrate 22-2, the first cooling section 50-1, and the second cooling section 50-2 at the position of the line A-A′ shown in FIG. 4. The test circuits 24 are arranged in the flow paths 64 formed on the substrate surfaces that are respectively opposite the first test substrate 22-1 and the second test substrate 22-2. It should be noted that the third cooling section 50-3 and the fourth cooling section are omitted from the view shown in FIG. 6.

As described above, the contact portion 56 of each cooling section 50 is formed at a position corresponding to the end portion of the flow path 64. The contact portion 56 is harder to bend than the other regions at the ceiling portion 54. For example, the contact portion 56 can be thicker than other regions at the ceiling portion 54. Here, the thickness refers to the thickness in a direction perpendicular to the substrate surface of the test substrate 22.

Each contact portion 56 is provided such that the bottom surface thereof is on the substrate surface of the corresponding test substrate 22. Among the contact portions 56, those in regions corresponding to the connection opening 52 and the flow path 64 have bottom surfaces that do not contact the substrate surface of the test substrate 22. Furthermore, at least a partial region of the ceiling portion 54 that is not the contact portion 56 does not contact the substrate surface of the corresponding test substrate 22. For example, the region of the ceiling portion 54 corresponding to the flow path 64 does not contact the substrate surface of the test substrate 22.

For two ceiling portions 54 that are opposite each other, at least a partial region of each ceiling portion 54, other than the contact portion 56, need not be in contact with the partial region of the other. In other words, a cavity 62 may be formed between two opposite ceiling portions 54. For example, in a region of a ceiling portion 54 other than the contact portion 56, the cavity 62 is formed in the region corresponding to the flow path 64. In this way, even when pressure is placed on the ceiling portion 54 by the cooling medium, for example, this force can be absorbed by deformation of the ceiling portion 54.

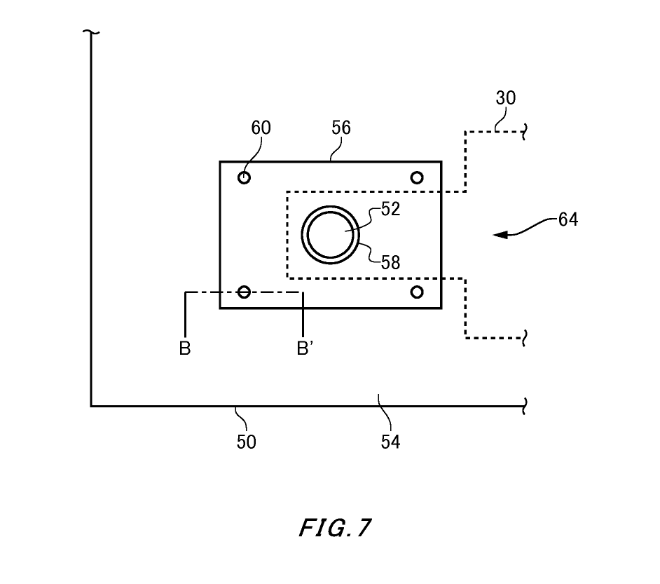

FIG. 7 shows an exemplary contact portion 56 and flow path 64. As described above, the connection opening 52 is formed at a position opposite the end portion of the flow path 64. The end portion of the flow path 64 may have a smaller width than the region in which the test circuit 24 is formed. Here, the width refers to the width in a direction that is parallel to the substrate surface of the test substrate 22 and orthogonal to the direction in which the cooling medium progresses.

In this example, the width of the end portion of the flow path 64 is less than the width of the contact portion 56. The contact portion 56 in this example is formed by cleaving the end portion of the flow path 64 in the width direction. Furthermore, at least two screw holes 60 are provided to sandwich the end portion of the flow path 64 in the width direction. The screw holes 60 are provided in a region where the contact portion 56 contacts the test substrate 22. The width of the contact portion 56 may be less than the width of the flow path 64 where the test circuit 24 is provided.

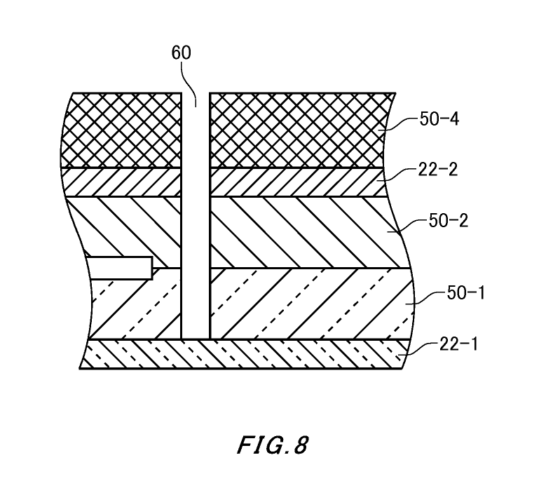

FIG. 8 shows an exemplary cross section of the first test substrate 22-1, the second test substrate 22-2, the first cooling section 50-1, the second cooling section 50-2, and the fourth cooling section 50-4, at the position of the line B-B′ in FIG. 7. The screw holes 60 are provided across the first cooling section 50-1 and the second cooling section 50-2. By inserting screws into the screw holes 60, the contact portions 56 of the first cooling section 50-1 and the second cooling section 50-2 can be secured to each other. FIG. 8 shows the screw holes 60 penetrating through the first cooling section 50-1, but the screw holes 60 need not penetrate through the first cooling section 50-1.

As shown in FIG. 8, the screw holes 60 may be formed in the fourth cooling section 50-4 and the second test substrate 22-2 as well. The screws inserted into the screw holes 60 secure the fourth cooling section 50-4, the second test substrate 22-2, the first cooling section 50-1, and the second cooling section 50-2. In this way, the contact portions 56 of the first cooling section 50-1 and the second cooling section 50-2 can be easily secured to each other, by inserting a screw from the fourth cooling section 50-4 side. Each test substrate 22 and each cooling section 50 are secured by means such as other screws.

The screw hole 60 may be formed in the third cooling section 50-3, the first test substrate 22-1, the first cooling section 50-1, and the second cooling section 50-2. In this case, the screw is inserted from the third cooling section 50-3 side. The screw hole 60 may be formed in the third cooling section 50-3, the first test substrate 22-1, the first cooling section 50-1, the second cooling section 50-2, the second test substrate 22-2, and the fourth cooling section 50-4. In this case, the screw is inserted from the third cooling section 50-3 side or the fourth cooling section 50-4 side.

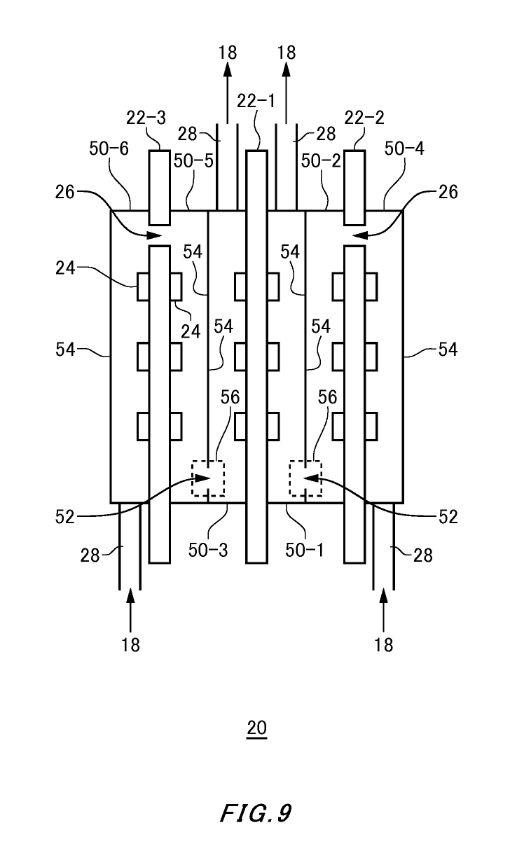

FIG. 9 shows another exemplary configuration of the circuit substrate unit 20 according to a second embodiment. The circuit substrate unit 20 of this example includes a first test substrate 22-1, a second test substrate 22-2, a third test substrate 22-3, test circuits 24, a first cooling section 50-1, a second cooling section 50-2, a third cooling section 50-3, a fourth cooling section 50-4, a fifth cooling section 50-5, a sixth cooling section 50-6, and a plurality of external connecting sections 28. In this example, components that have the same reference numeral as in the circuit substrate unit 20 shown in FIG. 2A may have the same or similar function and configuration as the components of the circuit substrate unit 20 shown in FIG. 2A. The first test substrate 22-1 of this example differs from the first test substrate 22-1 in the circuit substrate unit 20 shown in FIG. 2A by not including the through-hole 26 that connects the front and back substrate surfaces.

The third test substrate 22-3 is arranged opposite the first test substrate 22-1, on the opposite side of the second test substrate 22-2. The surface of the third test substrate 22-3 opposite the first test substrate 22-1 is the fifth substrate surface and the surface of the third test substrate 22-3 on the back side of the fifth substrate surface is the sixth substrate surface. The test circuits 24 are provided on the fifth and sixth substrate surfaces of the third test substrate 22-3. The third test substrate 22-3 includes a through-hole 26 that connects the fifth substrate surface to the sixth substrate surface.

The fifth cooling section 50-5 is provided on the fifth substrate surface of the third test substrate 22-3 and houses test circuits 24. The sixth cooling section 50-6 is provided on the sixth substrate surface of the third test substrate 22-3 and hoses test circuits 24.

The third cooling section 50-3 and the fifth cooling section 50-5 of the present example respectively include contact portions 56 that contact each other. Each contact portion 56 of the third cooling section 50-3 and the fifth cooling section 50-5 includes a connection opening 52 that connects the inside of the third cooling section 50-3 to the inside of the fifth cooling section 50-5.

The circuit substrate unit 20 in this example includes an external connecting section 28 for each of the first cooling section 50-1, the third cooling section 50-3, the fourth cooling section 50-4, and the sixth cooling section 50-6.

The external connecting section 28 connected to the sixth cooling section 50-6 introduces the cooling medium into the sixth cooling section 50-6. The cooling medium introduced into the sixth cooling section 50-6 is introduced into the fifth cooling section 50-5 through the through-hole 26. The cooling medium introduced into the fifth cooling section 50-5 is introduced into the third cooling section 50-3 through the connection opening 52. The cooling medium introduced into the third cooling section 50-3 is expelled by the external connecting section 28.

The external connecting section 28 connected to the fourth cooling section 50-4 introduces the cooling medium into the fourth cooling section 50-4. The cooling medium introduced into the fourth cooling section 50-4 is introduced into the second cooling section 50-2 through the through-hole 26. The cooling medium introduced into the second cooling section 50-2 is introduced into the first cooling section 50-1 through the connection opening 52. The cooling medium introduced into the first cooling section 50-1 is expelled by the external connecting section 28.

The paths for introducing and expelling of the cooling medium may be opposite. In the present example, the cooling medium is circulated by two systems, but as another example, a single system may be used to circulate the cooling medium, in the same manner as in the first embodiment. For example, the external connecting sections 28 of the first cooling section 50-1 and the third cooling section 50-3 may be removed and the first test substrate 22-1 may be provided with a through-hole 26, thereby introducing the cooling medium into the sixth cooling section 50-6 and expelling the cooling medium from the fourth cooling section 50-4.

The total amount of heat generated by the electronic circuits housed by the cooling sections 50 arranged upstream in the cooling medium flow path may be greater than the total amount of heat generated by the electronic circuits housed by the cooling sections 50 arranged downstream in the cooling medium flow path. For example, the total amount of heat generated by the electronic circuits housed by the sixth cooling section 50-6 may be greater than the total amount of heat generated by the electronic circuits housed by the third cooling section 50-3. As a result, the electronic circuits that generate a greater amount of heat can be efficiently cooled.

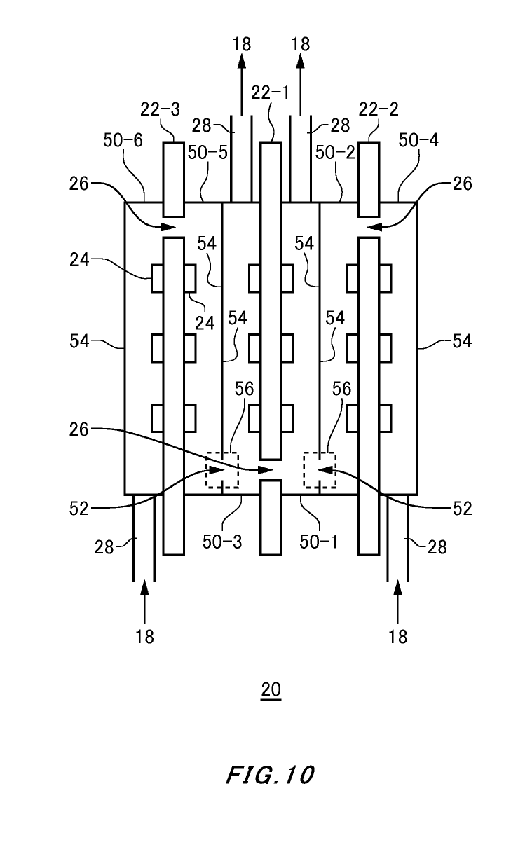

FIG. 10 shows another exemplary configuration of the circuit substrate unit 20. The circuit substrate unit 20 of the present example differs from the circuit substrate unit 20 shown in FIG. 9 in that the first test substrate 22-1 includes a through-hole 26. The remaining configuration of this circuit substrate unit 20 may be the same as that of the circuit substrate unit 20 shown in FIG. 9. The through-hole 26 is formed in the first test substrate 22-1 and connects the first substrate surface of the second test substrate 22-2 to the third substrate surface of the third test substrate 22-3.

With this configuration, the circulation system on the first substrate surface side of the first test substrate 22-1 can be connected to the circulation system on the third substrate surface side. Therefore, when the pressure of one of these circulation systems increases, this pressure can be released into the other circulation system.

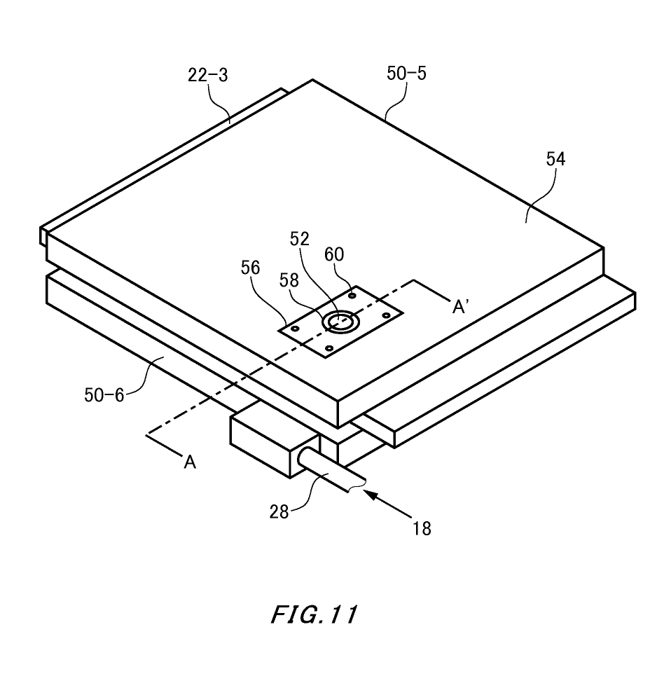

FIG. 11 shows an exemplary configuration of the third test substrate 22-3, the fifth cooling section 50-5, and the sixth cooling section 50-6. The third test substrate 22-3 in FIG. 11 may have the same configuration as the test substrate 22 shown in FIG. 3.

The external connecting section 28 is connected to the sixth cooling section 50-6. The external connecting section 28 introduces the cooling medium into the end portion of the flow path within the sixth cooling section 50-6 where the through-hole 26 shown in FIG. 3 is not provided. The introduced cooling medium propagates through the flow path within sixth cooling section 50-6, to be introduced into the fifth cooling section 50-5 from the through-hole 26.

The cooling medium introduced into the fifth cooling section 50-5 propagates through the flow path within the fifth cooling section 50-5, and reaches the end portion where the through-hole 26 is not provided. A contact portion 56 is provided on the ceiling portion 54 of the fifth cooling section 50-5, at a position opposite the end portion. The structure of the contact portion 56 may be the same as that of the contact portion 56 in the first embodiment.

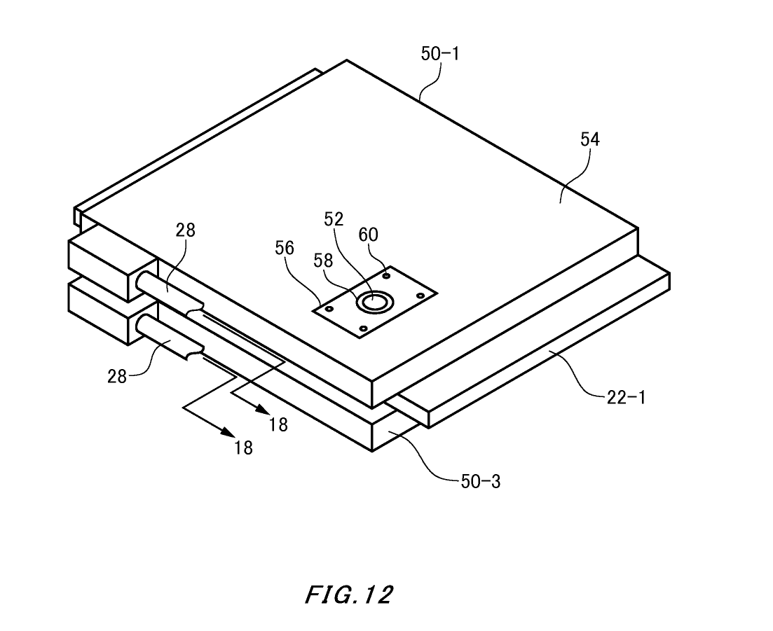

FIG. 12 shows an exemplary configuration of the first test substrate 22-1, the third cooling section 50-3, and the first cooling section 50-1. The first test substrate 22-1 of FIG. 12 includes the through-hole 26 formed at a different position than in the test substrate 22 shown in FIG. 3. The through-hole 26 of the first test substrate 22-1 is provided at or near a position overlapping with at least one of the connection opening 52 connecting the insides of the first cooling section 50-1 and the second cooling section 50-2 and the connection opening 52 connecting the insides of the third cooling section 50-3 and the fifth cooling section 50-5.

In this example, the through-hole 26 of the first test substrate 22-1 and two connection openings 52 are provided at overlapping positions. With this example, the through-hole 26 of the first test substrate 22-1 and the two connection openings 52 are provided at overlapping positions, and therefore the pressure can be efficiently released between the two circulation systems.

The external connecting section 28 is connected to the third cooling section 50-3. The external connecting section 28 expels the cooling medium from the end portion of the flow path within the third cooling section 50-3 where the connection opening 52 is not provided.

The cooling medium is introduced into the first cooling section 50-1 from the second cooling section 50-2, through the connection opening 52. The external connecting section 28 for expelling the cooling medium is provided at the end portion of the flow path within the first cooling section 50-1 where the connection opening 52 is not provided.

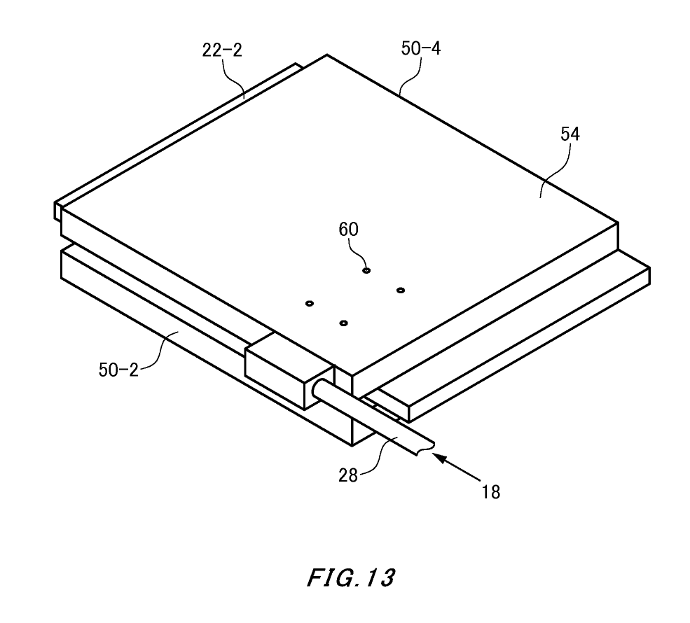

FIG. 13 shows an exemplary configuration of the second test substrate 22-2, the second cooling section 50-2, and the fourth cooling section 50-4. The configuration shown in FIG. 13 differs from the configuration shown in FIG. 5 in that the external connecting section 28 introduces the cooling medium into the fourth cooling section 50-4. The remaining configuration may be the same as shown in FIG. 5. The cooling medium introduced into the fourth cooling section 50-4 propagates through the path in a direction opposite the direction described in FIG. 5, and propagates to the first cooling section 50-1.

In the examples shown in FIGS. 9 to 13, the third cooling section 50-3 and the fifth cooling section 50-5 may be secured by screws inserted from the sixth cooling section 50-6 side. Furthermore, the first cooling section 50-1 and the second cooling section 50-2 may be secured by screws inserted from the fourth cooling section 50-4 side.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a first test substrate and a second test substrate arranged facing each other;
test circuits provided respectively on a first substrate surface of the first test substrate that faces the second test substrate and on a second substrate surface of the second test substrate that faces the first test substrate;
a first cooling section that is provided on the first substrate surface of the first test substrate in a manner to house the test circuit, and is to have a cooling medium introduced therein; and
a second cooling section that is provided on the second substrate surface of the second test substrate in a manner to house the test circuit, and is to have a cooling medium introduced therein, wherein
the first cooling section and the second cooling section include respective contact portions that are in contact with each other, and
each contact portion is provided with a connection opening that connects inside of the first cooling section and inside of the second cooling section to each other.

2. The test apparatus according to claim 1, wherein
the first cooling section and the second cooling section each include a ceiling portion provided opposite the corresponding substrate surface of the test substrate, and
the contact portions are provided on the ceiling portions.

3. The test apparatus according to claim 2, wherein
at least a portion of each contact portion contacts the corresponding substrate surface of the test substrate and at least a partial region of the ceiling portion that is not the contact portion does not contact the corresponding substrate surface of the test substrate.

4. The test apparatus according to claim 1, further comprising:
a test circuit that is provided on a third substrate surface of the first test substrate, which is a surface on a back side of the first substrate surface;
a third cooling section that is provided on the third substrate surface of the first test substrate in a manner to house the test circuit, and is to have a cooling medium introduced therein; and
an external connecting section through which the cooling medium propagates between the third cooling section and outside, wherein
a through-hole that connects the third substrate surface and the first substrate surface to each other is formed in the first test substrate.

5. The test apparatus according to claim 4, further comprising:
an external connecting section through which the cooling medium propagates between the second cooling section and the outside.

6. The test apparatus according to claim 4, further comprising:
a test circuit that is provided on a fourth substrate surface of the second test substrate, which is a surface on a back side of the second substrate surface; and
a fourth cooling section that is provided on the fourth substrate surface of the second test substrate in a manner to house the test circuit, and is to have a cooling medium introduced therein.

7. The test apparatus according to claim 6, wherein
the through-hole is provided at a position overlapping the connection opening that connects the inside of the first cooling section and the inside of the second cooling section to each other.

8. A circuit substrate unit comprising:
a first circuit substrate and a second circuit substrate arranged facing each other;
electrical circuits provided respectively on a first substrate surface of the first circuit substrate that faces the second circuit substrate and on a second substrate surface of the second circuit substrate that faces the first circuit substrate;
a first cooling section that is provided on the first substrate surface of the first circuit substrate in a manner to house the electrical circuit, and is to have a cooling medium introduced therein; and
a second cooling section that is provided on the second substrate surface of the second circuit substrate in a manner to house the electrical circuit, and is to have a cooling medium introduced therein, wherein
the first cooling section and the second cooling section include respective contact portions that are in contact with each other, and
each contact portion is provided with a connection opening that connects inside of the first cooling section and inside of the second cooling section to each other.
